(19) United States
(12) Patent Application Publication
(10) Pub. No.: US 2002/0149388 A1
(43) Pub. Date: Oct. 17, 2002

(54) Method for the accurate electrical testing of semiconductor devices

(76) Inventor: Cleston Messick, Sandy, UT (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/833,462

(22) Filed: Apr. 11, 2001

(51) Int. Cl. G01R 31/26

(52) U.S. Cl. 324/765

(57) ABSTRACT

An electrical test method that provides an accurate, high throughput measurement of semiconductor device electrical characteristics using four-point test methods at the wafer-level. An electrical characteristic (e.g., RDSon) of at least one semiconductor device (e.g., a discrete power semiconductor device in wafer form) is first measured, using a four-point test method with a first force electrical connection and a first sense electrical connection, and recorded as a first measurement. The first force electrical connection and the first sense electrical connection are then transposed (i.e., swapped or switched) to provide a second force electrical connection and a second sense electrical connection. The electrical characteristic is subsequently re-measured, and recorded as a second measurement, using the four-point test method, the second force electrical connection and the second sense electrical connection. The recorded first and second measurements are then compared and one of them is selected as the more accurate measurement of the two. The force and sense electrical connections can be provided to a semiconductor device in wafer form via a Kelvin chuck.

### BACKGROUND OF THE INVENTION

1. Field of the Invention

The present invention relates, in general, to semiconductor devices and, in particular, to semiconductor device electrical test methods.

2. Description of the Related Art

It is a common industry practice for semiconductor devices (including discrete power semiconductor devices) to be marketed with data sheets. These data sheets provide customers with various electrical characteristics of the semiconductor devices including, for example, a guaranteed range of resistances at specified currents and control gate voltages. To meet such guarantees, the semiconductor devices are screened (i.e., tested) for these electrical characteristics using electrical test methods. Since the assembly and packaging of individual semiconductor devices is costly, it is beneficial to screen the semiconductor devices as early in their manufacturing process as possible, for example, when the semiconductor devices are still in wafer form.

The measurement of low semiconductor device resistances using electrical test methods (e.g., resistances of less than 50 milli-ohms) requires the application of high currents (e.g., currents greater than 1 amp) to the semiconductor devices. However, the electrical connections between an electrical test apparatus and a wafer-level semiconductor device (i.e., a semiconductor device still in wafer form) include inherent series resistances that can cause inaccurate measurements upon electrical test. Electrical testing of wafer-level semiconductor devices, therefore, often leads to either over-rejection (i.e., the improper rejection of semiconductor devices that meet electrical specifications) or under-rejection (i.e., the improper passing of semiconductor devices that fail electrical specifications when tested at subsequent, more costly, screening points).

It can be desirable to test a semiconductor device using a four-point test method that employs separate force and sense electrical connections to the semiconductor device. These separate electrical connections provide for the sensing path to be outside the series resistance of the current (i.e., force) path. Since only a negligible amount of current travels in the sensing path, only a small voltage drop occurs across the sensing path. This small voltage drop enables an accurate voltage measurement.

Applying a conventional four-point test method to wafer-level semiconductor devices has, however, been problematic since a chuck which holds the wafer during such testing must be divided into separate force and sense portions. This division results in a current path length that is dependent on the location of the semiconductor device on the wafer, thereby making the current path length variable. The variable current path length, which is essentially the distance between the force portion of the chuck and the semiconductor device, produces a variable series resistance in the current path. Applying a four-point test method to wafer-level semiconductor devices will, therefore, cause non-uniform resistance measurements depending on the position of the semiconductor device on the wafer.

Various semiconductor devices can be screened using tester-on-a-pin methods, wherein multiple semiconductor devices are tested at the same time, thus increasing the throughput of the associated electrical test apparatus. However, since each semiconductor device being tested requires its own computer controlled power supply, and high current power supplies are expensive, tester-on-a-pin methods are not usually implemented to measure low semiconductor device resistances.

Some semiconductor devices can be screened using an electrical test method referred to as “ping-pong” mode testing. Ping-pong mode testing uses separate first and second probing apparatus (i.e., first and second probers) to make electrical connections to individual semiconductor devices. The first and second probers can be selectively connected to a single measurement system of an electrical test apparatus and can move from one semiconductor device to another. When the first prober is utilizing the single measurement system to test a first semiconductor device, the second prober is moving to the next semiconductor device to be tested. When testing is complete on the first semiconductor device, the single measurement system is selectively connected to the second prober and the next semiconductor device is tested while the first prober moves to another semiconductor device. To maximize the throughput of the electrical test apparatus during ping-pong mode testing, testing time must be approximately equal to the time required for the probers to move from one semiconductor device to another semiconductor device, typically approximately 150 to 250 milliseconds.

Still needed in the field, therefore, is an inexpensive electrical test method that enables an accurate measurement of semiconductor device electrical characteristics using four-point test methods. In addition, the electrical test method should be suitable for testing semiconductor devices at the wafer level, have a high throughput and be compatible with ping-pong mode testing.

### SUMMARY OF THE INVENTION

The present invention provides an inexpensive electrical test method that enables an accurate measurement of semiconductor device electrical characteristics using four-point test methods. In addition, the semiconductor device electrical test method is suitable for testing semiconductor devices at the wafer level, has a high throughput and is compatible with ping-pong mode testing.

One exemplary embodiment of the present invention is a semiconductor device electrical test method that includes measuring an electrical characteristic (e.g., RDSon) of at least one semiconductor device (e.g., a plurality of discrete power semiconductor devices in wafer form) and recording a first measurement using a four-point test method. In this embodiment, the four-point test method employs a first force electrical connection and a first sense electrical connection. Next, the first force electrical connection and the first sense electrical connection are transposed (i.e., swapped or switched) to provide a second force electrical connection and a second sense electrical connection. This transposition is accomplished such that the first force electrical connection becomes the second sense electrical connection, while the first sense electrical connection becomes the second force electrical connection. The electrical characteristic of the semiconductor device(s) is then re-measured, and recorded as a second measurement, using the four-point test method. This re-measurement employs the second force electrical connection and the second sense electrical connection. The recorded first and second measurements are then compared and one of them is selected as a more accurate measurement of the two.

By employing a four-point test method, the inherent series resistance present upon provision of electrical connections between an electrical test apparatus and a semiconductor device is reduced, thereby increasing the accuracy of measurements taken. By measuring the electrical characteristic of the semiconductor device twice, and then selecting one of the measurements as more accurate, measurement dependency on the respective location of the sense and force electrical connections and the semiconductor device is reduced, thereby further increasing accuracy in the measurements. In addition, methods in accordance with the present invention require only one high current power supply and are, therefore, inexpensive.

A better understanding of the features and advantages of the present invention will be obtained by reference to the following detailed description that sets forth illustrative embodiments, in which the principles of the invention are utilized, and the accompanying drawings.

### BRIEF DESCRIPTION OF THE DRAWINGS

FIG. 1 is a flow diagram illustrating the sequence of a process according to one exemplary embodiment of the present invention; and

FIG. 2 is a flow diagram illustrating the sequence of a process according to another exemplary embodiment of the present invention.

### DETAILED DESCRIPTION OF THE INVENTION

To be consistent throughout the present specification and for clear understanding of the present invention, the following definitions are hereby provided for terms used therein:

The term “Kelvin chuck” refers to a wafer chuck that has at least two separate sense and force portions for providing force and sense electrical connections to the backside of a wafer.

The term “RDSon” is defined as the resistivity between the drain region and the source region of a semiconductor device in the on-state.

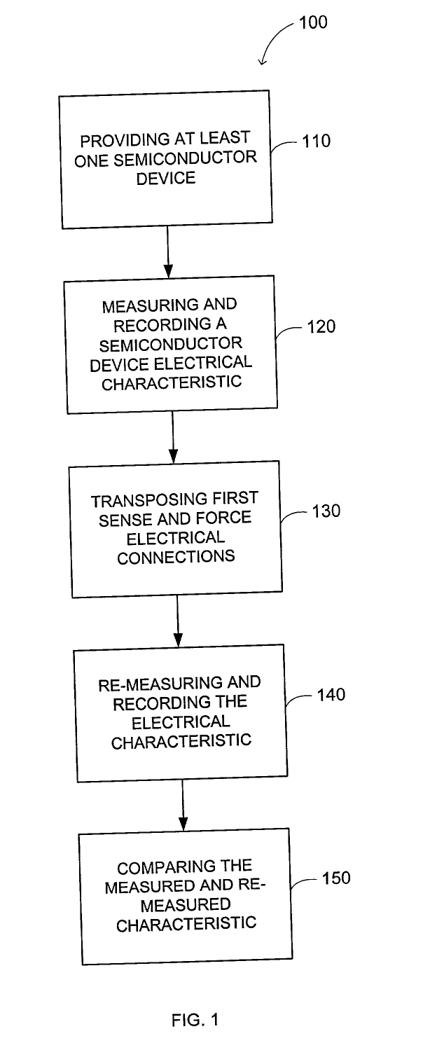

FIG. 1 illustrates steps in a process 100 that provides a semiconductor device electrical test method according to one exemplary embodiment of the present invention. At least one semiconductor device (e.g., a discrete power semiconductor device) is first provided, as shown at step 110. The semiconductor device(s) can be in wafer form, packaged form or any other suitable form known to one skilled in the art. Next, an electrical characteristic of the semiconductor device is measured using a four-point test method that employs a first force electrical connection and a first sense electrical connection. The measured electrical characteristic is also recorded as a first measurement, as shown at step 120.

Measured electrical characteristics can include RDSon, a semiconductor device capacitance characteristic, a semiconductor device leakage characteristic and any other semiconductor device electrical characteristic that can be measured using a four-point test method. The measurement of RDSon can, for example, involve a four-point test method that measures (i.e., senses) a voltage in the range of 2 milli-volts to 10 milli-volts using a forced current in the range of 1 amp to 3 amps. If desired, RDSon can be measured across a range of known currents and a range predetermined voltages applied to the control gate. For example, RDSon can be measured three times using three predetermined voltages applied to the control gate. Furthermore, the three predetermined voltages can be selected such that RDSon measurements are made in both the non-linear-increasing and the saturation operating regimes of the semiconductor device. The measurement of a semiconductor device capacitance characteristic can, for example, involve forcing a voltage frequency and sensing a voltage timing response (which is a function of both capacitance and resistance in the semiconductor device). The measurement of a semiconductor device leakage characteristic can, for example, involve the forcing of a predetermined voltage and the sensing of a resultant leakage current. When the semiconductor device is provided in wafer form, the first sense electrical connection and the first force electrical connection can, for example, be made to the substrate of the semiconductor device via a Kelvin chuck. When the semiconductor device is provided in packaged form, the first sense electrical connection and the first force electrical connection can, for example, be made to the package via Kelvin-type connections.

Next, the first force electrical connection and the first sense electrical connection are transposed (i.e., swapped or switched) to provide a second force electrical connection and a second sense electrical connection, as illustrated at step 130. This transposition is conducted such that the first force electrical connection becomes the second sense electrical connection, while the first sense electrical connection becomes the second force electrical connection. The transposition is accomplished by, for example, transposing the force and sense electrical connections on a drain region of the semiconductor device. Furthermore, when the first force electrical connection and first sense electrical connection are made via a Kelvin chuck, the transposition can be accomplished by transposing the sense and force portions of the Kelvin chuck.

The electrical characteristic of the semiconductor device is then re-measured using the four-point test method, as shown at step 140. However, during this re-measurement, the four-point test method uses the second force electrical connection and the second sense electrical connection. The electrical characteristic re-measured during this step is recorded as a second measurement. The second sense electrical connection and the second force electrical connection of the re-measuring step can, form example, be made to the substrate of the semiconductor device via the Kelvin chuck.

Next, the recorded first measurement and the recorded second measurement are compared and one of them is selected as a more accurate measurement, as shown at step 150. For example, in the circumstance where the electrical characteristic is RDSon, the lower of the first measured RDSon and the second measured RDSon is selected as the more accurate measurement of RDSon. The lower measurement of RDSon is assumed to have been produced by a measurement or re-measurement step that involved the shortest possible force path, thereby making the measurement more accurate. In practice, a typical percentage difference between the recorded first RDSon measurement and the recorded second RDSon measurement can be, for example, as high as 50% (which is equivalent to approximately 2 milli-volts of sensed voltage).

When testing a plurality of semiconductor devices, the throughput of conventional electrical test methods can be limited by the need to operate a high current power supply of an electrical test apparatus in a time-consuming discontinuous manner as the testing proceeds from one semiconductor device to the next. However, when testing a plurality of semiconductor devices, measurement and re-measurement steps 120, 140 can provide for the continuous operation of a high current power supply by (i) measuring the electrical characteristic of the first semiconductor device after the first semiconductor device has been placed in an on-state; (ii) placing the second semiconductor device in the on-state; and (iii) subsequently placing the first semiconductor device in an off-state. Since at least one semiconductor device is always in the on-state, the high current power supply can be continuously operated during either or both of the measurement and re-measurement steps. Therefore, processes according to the present invention have a high throughput and testing times that are compatible with ping-pong mode test methods.

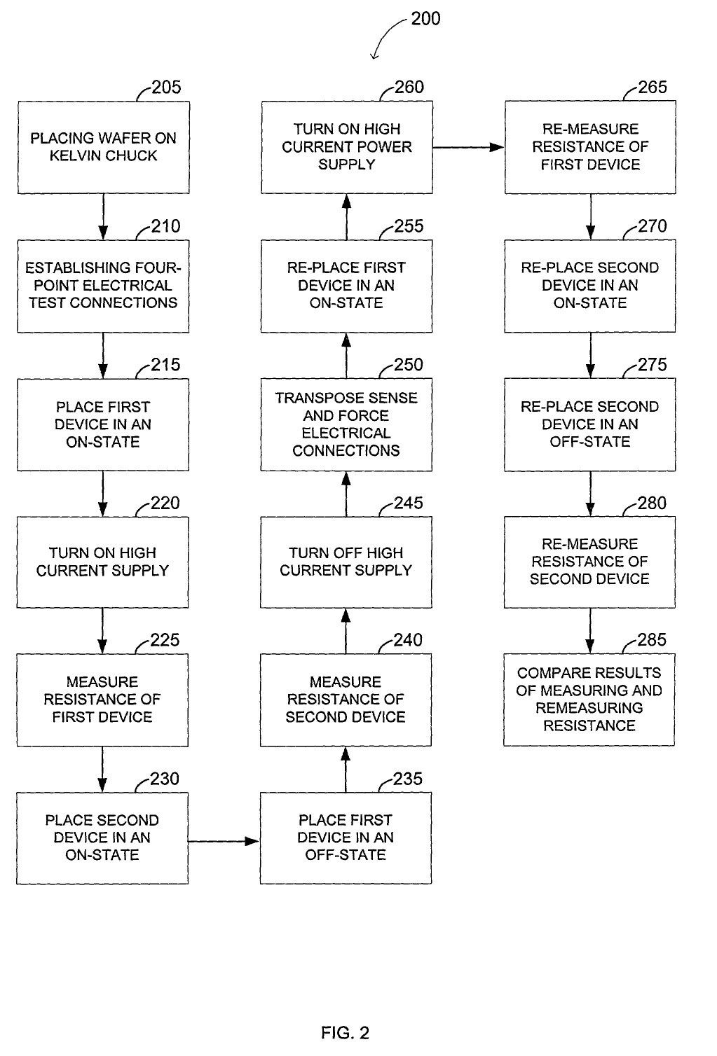

FIG. 2 is a flow diagram illustrating a sequence of steps in process 200 for accurately measuring the resistance of a plurality of discrete power semiconductor devices in wafer form in accordance with one exemplary embodiment of the present invention. A wafer with a plurality of discrete power semiconductor devices formed thereon is first placed on a Kelvin chuck of an electrical test apparatus, as shown at step 205. Each of the discrete power semiconductor devices includes a control gate and a substrate-drain region. One skilled in the art will recognize that the term “substrate-drain region” refers to a discrete power semiconductor device configuration wherein the wafer substrate serves as the drain region. In addition to a Kelvin chuck, the electrical test apparatus includes a high current power supply and a control gate voltage supply. The electrical test apparatus can be any suitable electrical test apparatus known in the art, including commercially available electrical test apparatus available from FETTEST (e.g., an FETTEST 3300 and 3600 electrical test apparatus), TMT and Eagle (e.g., an Eagle 500 and 300 electrical test apparatus).

Next, at step 210, four-point test method electrical connections are established to each of the multiple discrete power semiconductor devices. The electrical connections include a first sense electrical connection and a first force electrical connection to the substrate-drain regions of the multiple discrete power semiconductor devices via the sense and force portions of the Kelvin chuck, respectively. It should be noted that the multiple discrete power semiconductor devices can encompass the entire plurality of the discrete power semiconductor devices or a sub-set thereof. By establishing simultaneous electrical connections to multiple devices, the throughput of process 200 is increased.

A predetermined voltage is then applied to the control gate of a first discrete power semiconductor device, using the control gate voltage supply, as shown at step 215. The predetermined voltage is sufficient to place the first discrete power semiconductor device in an on-state. The high current power supply of the electrical test apparatus is then turned on and stabilized in step 220. The resistance (i.e., RDSon) of the first discrete power semiconductor device is then measured, as shown at step 225, using the four-point test method electrical connections. The measurement of resistance can be accomplished by forcing a known current through the discrete power semiconductor device (using the first force electrical connection and the high current power supply) and measuring the resulting voltage (using the first sense electrical connection). Once the current and voltage are known, the resistance (RDSon) can be calculated. If desired, the resistance can be measured across a range of known currents and a range of predetermined voltages applied to the control gate. For example, the resistance can be measured three times using three predetermined voltages applied to the control gate. Furthermore, the three predetermined voltages can be selected such that RDSon measurements are made in both the non-linear-increasing and the saturation operating regimes of the discrete power semiconductor device. In this manner, the test results required to guarantee a range of resistances at specified currents and control gate voltages can be collected.

At step 230, the predetermined voltage is applied to the control gate of a second discrete power semiconductor device, using the control gate voltage supply, to place the second discrete power semiconductor in an on-state. The predetermined voltage can be applied to the control gate of the second discrete power semiconductor device by, for example, a switch. Since only an insignificant level of current flows to the control gate, such switching can occur without interrupting operation of the control gate voltage supply. The predetermined voltage is subsequently removed from the control gate of the first discrete power semiconductor device (see step 235), thereby placing the first discrete power semiconductor device in an off-state. The sequence of steps 230 and 235 insure that at least one of the first and second discrete power semiconductor devices is in an on-state during the measurement of RDSon (i.e., during steps 225-240). This provides for the high current power supply to be operated in a continuous manner during steps 225-240. By operating the high current power supply in a continuous manner, there is no need to wait for stabilization between measurements. The result is an economical, and high throughput semiconductor device electrical test method that is compatible with ping-pong mode testing.

Next, the resistance of the second discrete power semiconductor device is measured using the four-point test method electrical connections (see step 240), followed by the turning off of the high current power supply (see step 245). The first force electrical connections and the first sense electrical connections are then transposed to provide a second force electrical connection and a second sense electrical connection, as shown at step 250. The transposition is accomplished such that the first force electrical connection becomes the second sense electrical connection, while the first sense electrical connection becomes the second force electrical connection.

Next, the predetermined voltage is re-applied to the control gate of the first discrete power semiconductor device, using the control gate voltage supply, to place the first discrete power semiconductor device in the on-state, as shown at step 255. The high current power supply is again turned on and stabilized (step 260) and the resistance of the first discrete power semiconductor device re-measured using the four-point test method electrical connections (see step 265). The predetermined voltage is then re-applied to the control gate of the second discrete power semiconductor device at step 270, using the control gate power supply, to place the second discrete power semiconductor in the on-state. The predetermined voltage is subsequently removed from the control gate of the first discrete power semiconductor device to replace the first discrete power semiconductor device in an off-state, as shown at step 275.

The resistance of the second discrete power semiconductor device is re-measured using the four-point test method electrical connections, as illustrated at step 280. A result of measuring the resistance of the first discrete power semiconductor and a result of re-measuring the resistance of the first discrete power semiconductor are then compared and the lower of the results accepted as the more accurate result, as shown at step 285. Results from the measurement and re-measurement of the resistance of the second discrete power semiconductor are also compared and the lower of the two accepted as the most accurate measurement.

Once apprised of the current disclosure, one skilled in the art will recognize that process 200 can be modified to measure more than two discrete power semiconductor devices prior to turning off the high current power supply in step 245 and transposing the first force electrical connection and the first sense electrical connection in step 250. This modification can be accomplished, for example, by essentially repeating steps 230-240 on additional discrete power semiconductor devices. The only limit to such a modification being the number of discrete power semiconductor devices to which four-point electrical test connections are established in step 210.

As discussed earlier, when testing a plurality of semiconductor devices, the throughput of conventional electrical test methods can be limited by the need to operate an electrical test apparatus' high current power supply in a time-consuming discontinuous manner. This drawback is present whether the electrical test method is a two-point method, four-point method or other method known to those skilled in the art. However, when testing a plurality of semiconductor devices, another embodiment of a method according to the present invention enables the continuous operation of a high current power supply by (i) measuring an electrical characteristic of a first semiconductor device after the first semiconductor device has been placed in an on-state; (ii) then placing a second semiconductor device in the on-state; (iii) subsequently placing the first semiconductor device in the off-state; and (iv) measuring the electrical characteristic of the second semiconductor device. Since at least one semiconductor device is always in the on-state, the high current power supply can be continuously operated during the method. Therefore, the method can operate with high throughput.

It should be understood that various alternatives to the embodiments of the invention described herein may be employed in practicing the invention. It is intended that the following claims define the scope of the invention and that methods within the scope of these claims and their equivalents be covered thereby.

What is claimed is:

1. A semiconductor device electrical test method for measuring an electrical characteristic of a semiconductor device comprising:
measuring and recording, as a first measurement, an electrical characteristic of at least one semiconductor device using a four-point test method, wherein the measuring employs a first force electrical connection and a first sense electrical connection;
transposing the first force electrical connection and the first sense electrical connection to provide a second force electrical connection and a second sense electrical connection in such a manner that the first force electrical connection becomes the second sense electrical connection and the first sense electrical connection becomes the second force electrical connection;
re-measuring and recording, as a second measurement, the electrical characteristic of the semiconductor device using the four-point test method, wherein the remeasuring employs the second force electrical connection and the second sense electrical connection; and
comparing the recorded first measurement and the recorded second measurement and selecting ore of them as the more accurate measurement of the two.

2. The semiconductor device electrical test method of claim 1 wherein the measuring and recording step measures and records an electrical characteristic of at least one semiconductor device in wafer form, and wherein the re-measuring and recording step re-measures and records an electrical characteristic of at least one semiconductor device in wafer form.

3. The semiconductor device electrical test method of claim 2 further comprising, during the measuring and recording step, employing a four-point test method wherein the first sense electrical connection and the first force electrical connection are made to a substrate of the semiconductor device via a Kelvin chuck; and
during the re-measuring and recording step, employing the four-point test method wherein the second sense electrical connection and the second force electrical connection are made to the substrate of the semiconductor device via the Kelvin chuck.

4. The semiconductor device electrical test method of claim 3, wherein the transposing is accomplished by transposing sense and force portions of the Kelvin chuck.

5. The semiconductor device electrical test method of claim 1, wherein the measuring and recording step measures and records an electrical characteristic of at least one semiconductor device in packaged form, and wherein the re-measuring and recording step re-measures and records an electrical characteristic of at least one semiconductor device in packaged form.

6. The semiconductor device electrical test method of claim 1, wherein the electrical characteristic is RDSon.

7. The semiconductor device electrical test method of claim 6 further comprising, during the comparing step, selecting the lower of the first measurement of RDSon and the second measurement of RDSon as the more accurate measurement of RDSon.

8. The semiconductor device electrical test method of claim 6 further comprising, during the measuring and recording step, sensing a voltage in the range of 2 milli-volts to 100 milli-volts using currents in the range of 1 amp to 3 amps; and
during the re-measuring and recording step, sensing a voltage in the range of 2 milli-volts to 100 millivolts using currents in the range of 1 amp to 3 amps.

9. The semiconductor device electrical test method of claim 1, wherein the electrical characteristic is a semiconductor device leak age characteristic.

10. The semiconductor device electrical test method of claim 1, wherein the electrical characteristic is a semiconductor device capacitance characteristic.

11. The semiconductor device electrical test method of claim 1, wherein the measuring and recording step measures and records an electrical characteristic of at least one discrete power semiconductor device, and wherein the re-measuring and recording step re-measures and records an electrical characteristic of at least one discrete power semiconductor device.

12. The semiconductor device electrical test method of claim 1, wherein the transposing step is accomplished by transposing the first force electrical connection and the first sense electrical connection to a drain region of the semiconductor device.

13. The semiconductor device electrical test method of claim 1 further comprising, during the measuring and recording step, placing a first semiconductor device in an on-state, followed by placing a second semiconductor device in an on-state and subsequently placing the first semiconductor device in an off-state, thereby providing for a high current power supply to be continuously operating during the measuring and recording step.

14. The semiconductor device electrical test method of claim 1 further comprising, during the measuring and recording step, measuring an electrical characteristic at a plurality of applied voltages; and
during the re-measuring and recording step, re-measuring the electrical characteristic at the plurality of applied voltages.

15. A method for accurately measuring the resistance of a plurality of discrete power semiconductor devices in wafer form, the method comprising:
placing a wafer, with a plurality of discrete power semiconductor devices formed thereon, on a Kelvin chuck of an electrical test apparatus, wherein:
each of the discrete power semiconductor devices includes a control gate and a substrate drain region; and
the electrical test apparatus includes a high current power supply and a control gate voltage supply;
establishing four-point test method electrical connections to each of multiple discrete semiconductor devices, wherein the electrical connections include a first sense electrical connection and a first force electrical connection to the substrate drain regions of each of the multiple discrete power semiconductor devices;
applying a predetermined voltage to the control gate of a first discrete power semiconductor device, using the control gate voltage supply, to place the first discrete power semiconductor in an on-state;
turning on and stabilizing the high current power supply;
measuring the resistance of the first discrete power semiconductor device using the four-point test method electrical connections;
applying the predetermined voltage to the control gate of a second discrete power semiconductor device, using the control gate voltage supply, to place the second discrete power semiconductor in an on-state;
removing the predetermined voltage from the control gate of the first discrete power semiconductor device ito place the first discrete power semiconductor device in an off state;
measuring the resistance of the second discrete power semiconductor device using the four-point test method electrical connections;
turning the high current power supply off;
transposing the first force electrical connection and the first sense electrical connection to provide a second force electrical connection and a second sense electrical connection in such a manner that the first force electrical connection becomes the second sense electrical connection and the first sense electrical connection becomes the second force electrical connection;
re-applying the predetermined voltage to the control gate of the first discrete power semiconductor device, using the control gate power supply, to re-place the first discrete power semiconductor in the on-state;
re-turning on and re-stabilizing the high current power supply;
re-measuring the resistance of the first discrete power semiconductor device using the four-point test method electrical connections;
re-applying the predetermined voltage to the control gate of the second discrete power semiconductor device, using the control gate power supply, to place the second discrete power semiconductor device in the on-state;
re-removing the predetermined voltage from the control gate of the first discrete power semiconductor device to re-place the first discrete power semiconductor device in an off-state;
re-measuring the resistance of the second discrete power semiconductor device using the four-point test method electrical connections; and
comparing a result of measuring the resistance of the first discrete power semiconductor device and a result of re-measuring the resistance of the first discrete power semiconductor device and accepting the lower of the results as the most accurate.

16. The method of claim 15 further comprising, during each of the first measuring step and the second measuring step, measuring RDSon at a plurality of predetermined voltages applied to the control gate; and
during each of the first re-measuring step and the second re-measuring step, measuring RDSon at the plurality of predetermined voltages applied to the control gate.

17. A method for electrically testing a plurality of semiconductor devices comprising:
measuring an electrical characteristic of a first semiconductor device using a high current power supply after the first semiconductor device has been placed in an on-state;
placing a second semiconductor device in the on-state;
placing the first semiconductor device in an off-state; and
measuring the electrical characteristic of the second semiconductor device using the high current power supply;
wherein the high current power supply is operated in an continuous manner.

18. The method of claim 17, wherein the measuring steps are conducted using a two-point test method.

19. The method of claim 17, wherein the measuring steps are conducted using a four-point test method.
